(19) United States
(12) Patent Application Publication
(10) Pub. No.: US 2004/0251948 A1
(43) Pub. Date: Dec. 16, 2004

(54) ADJUSTABLE IMPEDANCE CIRCUIT

(76) Inventors: Chao-Cheng Lee, Tao-Yuan Hsien (TW); Chia-Jun Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/605,327

(22) Filed: Sep. 23, 2003

(30) Foreign Application Priority Data
Jun. 16, 2003 (TW) 092116307

(51) Int. Cl. H03L 5/00

(52) U.S. Cl. 327/308

(57) ABSTRACT

An impedance circuit for providing an equivalent impedance between a first node and a second node includes a first impedance for providing a first impedance value, a first switch element electrically connected to the first impedance, a second impedance for providing a second impedance value, and a second switch element electrically connected to the second impedance. The equivalent impedance is determined by the first impedance value and the second impedance value, and by controlling the turn on time and the turn off time of the first switch element and the second switch element.

### BACKGROUND OF INVENTION

1. Field of the Invention

The present invention relates to an impedance circuit, and more specifically, to an adjustable impedance circuit whose equivalent impedance is determined by controlling the duty cycle of a control signal.

2. Description of the Prior Art

There are two main problems when manufacturing a passive impedance device for an integrated circuit (IC). The first problem is concerned with the area occupied by large value passive impedance devices in an IC. For example, a resistor in an IC is often implemented by a metal line segment or polysilicon line segment, whose resistance is directly proportional to the length of the line segment. For another example, a capacitor in an IC is often implemented by a structure where a dielectric layer is inserted between two metal layers. The capacitance is directly proportional to the area of the structure. The second problem is concerned with low precision of the passive impedance devices manufactured by semiconductor manufacturing process. Since many factors that cause errors exist in the manufacturing process, it is impossible to manufacture a passive impedance device with its value matching a theoretical value according to the requirements of circuit design. Take a resistor for example, even under the same manufacturing conditions, minute differencesbetween resistances exist. Therefore, the precision of the equivalent impedance value of a resistor is limited due to differencesin the manufacturing process. Especially if trying to manufacture two resistors ofa similar value (e.g. two resistors with resistancesof R and R(1+e⁻⁶) respectively), the conventional semiconductor manufacturing process is not able to fulfill this requirement.

### SUMMARY OF INVENTION

It is therefore a primary objective of the present invention to provide an adjustable impedance circuit whose equivalent impedance is determined by controlling the duty cycle of a control signal, in order to solve the problems mentioned above.

Briefly summarized, an impedance circuit for providing an equivalent impedance between a first node and a second node includes a first impedance for providing a first impedance value, a first switch element electrically connected to the first impedance, a second impedance for providing a second impedance value, and a second switch element electrically connected to the second impedance. The equivalent impedance is determined by the first impedance value and the second impedance value, and by controlling the turn on time and the turn off time of the first switch element and the second switch element.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates an adjustable impedance circuit according to the first embodiment of the present invention.

FIG. 2 illustrates an adjustable impedance circuit according to the second embodiment of the present invention.

FIG. 3 is a clock diagram of the first control signal and the second control signal.

FIG. 4 is a flowchart of the operation of the adjustable impedance circuit according to the present invention.

### DETAILED DESCRIPTION

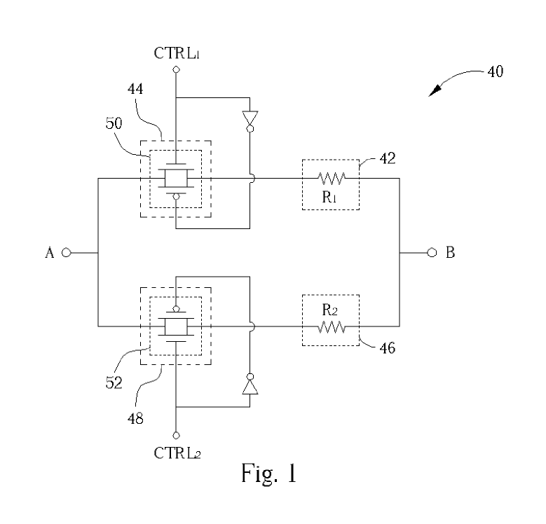

Please refer to FIG. 1 showing an adjustable impedance circuit 40 according to the first embodiment of the present invention. In this embodiment, a first impedance 42 is formed by a resistor having a resistance of R₁, a second impedance 46 is formed by a resistor having a resistance of R₂, and a first switch element 44 includes a first switch 50 for being turned on and off according to a first control signal CTRL₁. In this embodiment, the first switch 50 is a transmission gate composed of an NMOS transistor and a PMOS transistor. The gate of the NMOS transistor is electrically connected to the first control signal CTRL₁, and the gate of the PMOS transistor is electrically connected to the first control signal CTRL₁ through an inverter in order toaccurately turn on and turn off the transmission gate. A second switch element 48 includes a third switch 52 for being turned on and off according to a second control signal CTRL₂. In this embodiment, the second switch 52 is also a transmission gate composed of an NMOS transistor and a PMOS transistor. The gate of the NMOS transistor is electrically connected to the second control signal CTRL₂, and the gate of the PMOS transistor is electrically connected to the second control signal CTRL₂ through an inverter in order to accurately turn on and turn off the transmission gate. It should be noted that the first and the second switch 50, 52 can be NMOS or PMOS switch also.

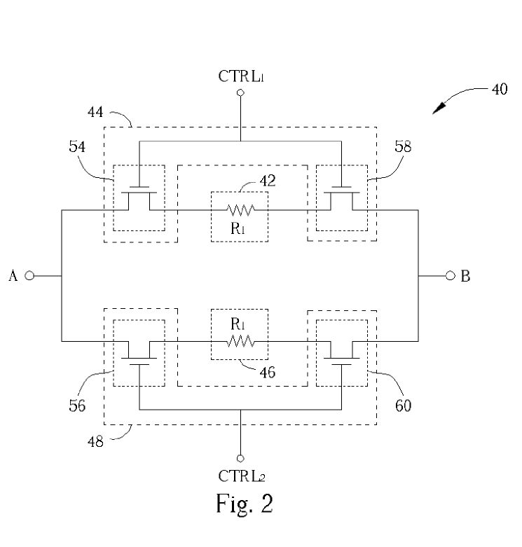

Please refer to FIG. 2 showing the adjustable impedance circuit 40 according to the second embodiment of the present invention. In this embodiment, the first switch element 44 further includes a second switch 58 electrically connected between a second node B and the other end of the first impedance 42, for being turned on and off according to the first control signal CTRL₁. And the second switch element 48 also includes a fourth switch 60 electrically connected between the second node B and the other end of the second impedance 46, for being turned on and off according to the second control signal CTRL₂.

In this embodiment, both the first switch 54 and the second switch 58 are NMOS transistors (as shown in FIG. 2). The gates of these NMOS transistors are electrically connected to the first control signal CTRL₁ for being accuratelyturned on and off according to the first control signal CTRL₁. The third switch 56 and the fourth switch 60 are also MOS transistors (as shown in FIG. 2). The gates of these MOS transistors are electrically connected to the second control signal CTRL₂ for being accurately turned on and off according to the second control signal CTRL₂.

Please notice that although the first impedance 42 and the second impedance 46 are resistors in the embodiments mentioned above, they could also be other impedance devices such as capacitors and inductors. Additionally, although the first impedance 42 and the second impedance 46 in the embodiments mentioned above are implemented by at least one transmission gate or at least one MOS transistor, other devices which can achieve the same purpose also belong to the present invention.

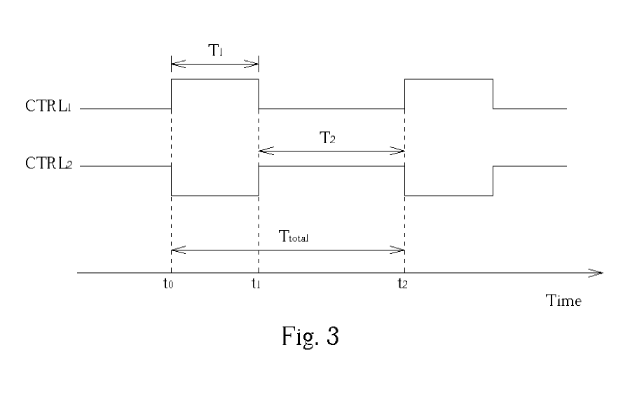

The operation of the adjustable impedance circuit 40 disclosed by the second embodiment of the present invention is further described as follows. Please refer to FIG. 3 showing a clock diagram of the first control signal CTRL₁ and the second control signal CTRL₂. In FIG. 3, the first control signal CTRL₁ is a periodic signal with a period of Ttotal. The first control signal CTRL₁ is at the high level for a duration of T₁, that is, the duty cycle of the first control signal CTRL₁ is DC₁=T₁/Ttotal. The second control signal CTRL₂ is also a periodical signal with a period of Ttotal. The second control signal CTRL₂ is at the high level for a duration of T₂, that is, the duty cycle of the second control signal CTRL₂ is DC₂=T₂/Ttotal. Since the first control signal CTRL₁ and the second control signal CTRL₂ are used to turn on and off a plurality of NMOS transistors, both the first control signal CTRL₁ and the second control signal CTRL₂ are active high signals.In other words, when the first control signal CTRL₁ and the second control signal CTRL₂ areat a high level, the NMOS transistors are turned on. Please notice that in FIG. 3, the first control signal CTRL₁ and the second control signal CTRL₂ are complementary signals. However, this is not a strict requirement. The first control signal CTRL and the second control signal CTRL₂ couldinstead be at a low level for a period of time.

As shown in FIG. 3, between time t₀ and time t₁, since the first control signal CTRL₁ is ata high level and the second control signal CTRL₂ is at a low level, the first switch element 44 in FIG. 2 is turned on so that the first impedance 42 is connected between a first node A and the second node B, and the second switch element 48 is turned off so that the second impedance 46 is not connected between the first node A and the second node B. Thus between time t₀ and time t₁, the impedance of the adjustable impedance circuit 40 is equivalent to the resistance R₁.

Between time t₁ and time t₂, since the first control signal CTRL₁ is at a low level and the second control signal CTRL₂ is at a high level, the first switch element 44 in FIG. 2 is turned off so that the first impedance 42 is not connected between the first node A and the second node B, and the second switch element 48 is turned on so that the second impedance 46 is connected between a first node A and the second node B. Thus between time t₁ and time t₂, the impedance of the adjustable impedance circuit 40 is equivalent to the resistance R₂.

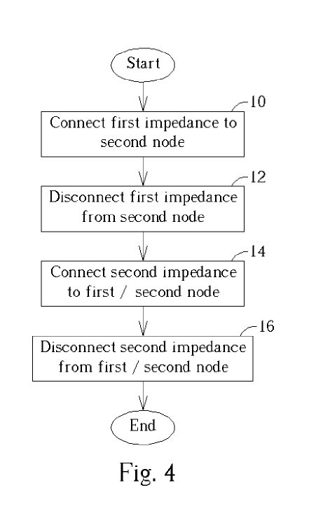

Please refer to FIG. 4 showing a flowchart of the operation of the adjustable impedance circuit according to the present invention. The flowchart comprises the following steps:

Step 10: Connect the first impedance to the second node.

Step 12: Disconnect the first impedance from the second node.

Step 14: Connect the second impedance to the first node and the second node.

Step 16: Disconnect the second impedance from the second node.

It should be noted that the first impedance and the second impedance are not necessarily alternatively connected or disconnected from the first node and the second node. They could also be connected and disconnected from the first node and the second node simultaneously.

As described above, if the time duration between time t₀ and time t₁ is T₁, and the time duration between time t₁ and time t₂ is T₂, when the first control signal CTRL₁ and the second control signal CTRL₂ switch periodically, the equivalent impedance Zeq between the first node A and the second node B can be represented by the following formula:

$$Zeq = \frac{{T}_{1} {R}_{1} + {T}_{2} {R}_{2}}{{T}_{total}} = D {C}_{1} {R}_{1} + D {C}_{2} {R}_{2} \qquad formula 1$$

In this embodiment, since the first control signal CTRL₁ and the second control signal CTRL₂ are complimentary signals, Ttotal=T₁+T₂, and DC₂=1−DC₁. Substitute these equations into formula 1 to obtain formula 2 as follows:

Zeq=DC₁RC₂+(1−DC₁)R₂ formula 2

For better performance, the frequencies of the first control signal CTRL₁ and the second control signal CTRL₂ are often higher than the operating frequency of the adjustable impedance circuit 40 (e.g. a factor of ten higher).

If two resistors havingsimilar values are required in an IC, two adjustable impedance circuits 40 can be used (hereinafter referred as adjustable impedance circuit 40a and adjustable impedance circuit 40b). Assume that in the adjustable impedance circuits 40a and 40b, R₁=2R₂, and a very minute difference exists between the duty cycle DC₁ₐ of the first control signal CTRL₁ of the adjustable impedance circuit 40a and the duty cycle DC_{1b} of the first control signal CTRL₁ of the adjustable impedance circuit 40b (e.g. DC₁ₐ=(1+e⁻⁶)DC_{1b}).The ratio of the equivalent impedance Zeqa of the adjustable impedance circuit 40a and the equivalent impedance Zeqb of the adjustable impedance circuit 40b can be obtained by the following formula:

$$\begin{matrix}\frac{Zeqa}{Zeqb} = \frac{( 1 + {ⅇ}^{- 6} ) D {C}_{1 b} \times 2 {R}_{2} + ( 1 - ( 1 + {ⅇ}^{- 6} ) D {C}_{1 b} ) {R}_{2}}{D {C}_{1 b} \times 2 {R}_{2} + ( 1 - D {C}_{1 b} ) {R}_{2}} \\ = 1 + \frac{{ⅇ}^{- 6}}{1 + \frac{1}{D {C}_{1 b}}}\end{matrix} \qquad formula 3$$

According to the result of formula 3, if the duty cycle DC_{1b} of the first control signal CTRL₁ of the adjustable impedance circuit 40b is 0.5, then Reqa=(1+e⁻⁶/3)Reqb.

As described above, the adjustable impedance circuit 40 according to the present invention achieves the purpose of manufacturing two impedancesof very close values by the control of the first control signal CTRL₁ and the second control signal CTRL₂. Since thepresent circuit design technology precisely controls the features of digital signals (e.g. the duty cycle of the first control signal and the second control signal), the present invention solves the problem of the conventional art.

Please notice that, in the embodiments mentioned above, the first control signal CTRL₁ and the second control signal CTRL₂ are implemented by complementary periodic signals as shown in FIG. 3. However according to practical requirements, the first control signal CTRL₁ and the second control signal CTRL₂ can also control the adjustable impedance circuit 40 so that the first impedance 42 and the second impedance 46 are simultaneously connected between the first node A and the second node B during a specific time period. In this time period, the equivalent impedance between the first node A and the second node B equals the parallel impedance of the first impedance 42 and the second impedance 46. The first control signal CTRL₁ and the second control signal CTRL₂ can also control the adjustable impedance circuit 40 so that the first impedance 42 and the second impedance 46 are simultaneously disconnected from the first node A and the second node B during a specific time period. In this time period, the first node A and the second node B are disconnected.

Those skilled in the art will readily observe that numerous modifications and alterations of the device may be made while retaining the teachings of the invention. Accordingly, the above disclosure should be construed as limited only by the metes and bounds of the appended claims.

1. An impedance circuit for providing an equivalent impedance between a first node and a second node comprising:
a first impedance for providing a first impedance value;
a first switch element electrically connected to the first impedance;
a second impedance for providing a second impedance value;
a second switch element electrically connected to the second impedance;
wherein the equivalent impedance is determined by the first impedance value and the second impedance value through controlling the turn on time and the turn off time of the first switch element and the second switch element.

2. The impedance circuit of claim 1, wherein the first impedance and the second impedance are resistors.

3. The impedance circuit of claim 1, further comprising a control circuit for generating a first control signal to turn on and turn off the first switch element, and a second control signal to turn on and turn off the second switch element.

4. The impedance circuit of claim 3, wherein the equivalent impedance is determined by controlling the duty cycle of the first control signal and the second control signal.

5. The impedance circuit of claim 3, wherein the first switch element comprises a first switch electrically connected between the first impedance and the first node, and the second switch element comprises a second switch electrically connected between the second impedance and the first node.

6. The impedance circuit of claim 3, wherein the first switch element comprises a first switch electrically connected between the first impedance and the first node, and the second switch element comprises a second switch electrically connected between the second impedance and the second node.

7. The impedance circuit of claim 1, wherein the first switch element comprises at least one first transmission gate turning on and off according to the first control signal, and the second switch element comprises at least one second transmission gate turning on and off according to the second control signal.

8. The impedance circuit of claim 1, wherein the first switch element comprises at least one first MOS transistor turning on and off according to the first control signal, and the second switch element comprises at least one second MOS transistor turning on and off according to the second control signal.

9. A method for controlling an impedance circuit to provide an equivalent impedance between a first node and a second node, the impedance circuit comprising a first impedance and a second impedance, the method comprising:
connecting the first impedance to the first node and the second node;
disconnecting the first impedance from the first node and the second node;
connecting the second impedance to the first node and the second node; and
disconnecting the second Impedance from the first node and the second node;
wherein the equivalent impedance is determined by the first impedance and the second impedance, and by controlling the connecting time of the first impedance and the second impedance to the first node and the second node.

10. The method of claim 9, wherein the first impedance and the second impedance are resistors.

11. The method of claim 9, wherein the first impedance and the second impedance are alternatively connected to the first node and the second node.

12. An impedance circuit for providing an equivalent impedance between a first node and a second node comprising:
a first impedance for providing a first impedance value;
a first switch element coupled to the first impedance;
a second impedance for providing a second impedance value; and
a second switch element coupled to the second impedance;
wherein the equivalent impedance is determined by continuously turning on and off the first switch element, and continuously turning on and off the second switch element.

13. The impedance circuit of claim 12, wherein the first switch element is controlled to turn on and off by a first periodic signal.

14. The impedance circuit of claim 13, wherein the second switch element is controlled to turn on and off by a second periodic signal.

15. The impedance circuit of claim 12, wherein the first impedance comprises a first resistor, and the second impedance comprises a second resistor.

16. The impedance circuit of claim 12, wherein the first impedance comprises a first capacitor, and the second impedance comprises a second capacitor.

17. The impedance circuit of claim 12, wherein the first impedance comprises a first inductor, and the second impedance comprises a second inductor.

18. The impedance circuit of claim 12, wherein a frequency of the continuous turning on and off of the first switch element and a frequency of the continuous turning on and off of the second switch element are both substantially higher than an operating frequency of the impedance circuit.

19. The impedance circuit of claim 18, wherein the frequency of the continuous turning on and off of the first switch element and the frequency of the continuous turning on and off of the second switch element are both at least ten times higher than the operating frequency of the impedance circuit.

20. An impedance circuit for providing an equivalent impedance between a first node and a second node comprising:
a first impedance for providing a first impedance value;
a first switch element coupled to the first impedance;
a second impedance for providing a second impedance value; and
a second switch element coupled to the second impedance;
wherein the equivalent impedance is determined by the first impedance value and the second impedance value through controlling frequencies of turning on and turning off the first switch element and the second switch element.

21. The impedance circuit of claim 20, wherein the frequencies of turning on and turning off the first switch element and the second switch element are both substantially higher than an operating frequency of the impedance circuit.

22. The impedance circuit of claim 21, wherein the frequencies of turning on and turning off the first switch element and the second switch element are both at least ten times higher than the operating frequency of the impedance circuit.
